(19) United States
(12) Patent Application Publication
(10) Pub. No.: US 2025/0321290 A1
(43) Pub. Date: Oct. 16, 2025

(54) BATTERY ABNORMALITY DETECTION SYSTEM, BATTERY ABNORMALITY DETECTION METHOD, AND NON-TRANSITORY COMPUTER-READABLE RECORDING MEDIUM

(71) Applicant: Panasonic Intellectual Property Management Co., Ltd., Osaka (JP)

(72) Inventor: Tomokazu SADA, Nara (JP)

(21) Appl. No.: 18/712,850

(22) PCT Filed: Nov. 15, 2022
(86) PCT No.: PCT/JP2022/042369

§ 371 Date: Oct. 2, 2024

(30) Foreign Application Priority Data
Nov. 29, 2021 (JP) 2021-192868

(51) Int. Cl. G01R 31/396; G01R 31/367; G01R 31/3835; G01R 31/392

(52) U.S. Cl. CPC G01R 31/396; G01R 31/367; G01R 31/3835; G01R 31/392

(57) ABSTRACT

A battery data acquisition unit acquires voltage data for each parallel cell block of a battery pack in which a plurality of parallel cell blocks, each comprised of a plurality of cells connected in parallel, are connected in series. An abnormality detection unit detects, based on a voltage change in a normal parallel cell block and on a change in a voltage difference between the normal parallel cell block and a target parallel cell block, an abnormality of the target parallel cell block.

### CROSS-REFERENCE TO RELATED APPLICATIONS

This application is based upon and claims the benefit of priority from the prior Japanese Patent Application No. 2021-192868, filed on Nov. 29, 2021, and the International Patent Application No. PCT/JP2022/042369, filed on Nov. 15, 2022, the entire content of each of which is incorporated herein by reference.

### BACKGROUND

### Field of the Invention

The present disclosure relates to a battery abnormality detection system, a battery abnormality detection method, and a battery abnormality detection program for detecting an abnormality in a battery.

### Description of the Related Art

In applications like EVs, battery packs in which a plurality of parallel cell blocks, each comprised of a plurality of cells connected in parallel, are connected in series are often used to increase the battery voltage and battery capacity. A method using an equalization circuit is proposed as a method for detecting an abnormal parallel cell block in a battery pack like this (see, for example, Patent Literature 1). In this method, an abnormal parallel cell block is detected by taking advantage of the fact that the time required for a parallel cell block including an abnormal cell to reach the target SOC (State Of Charge) is sped up during the equalization process.
Patent Literature 1: WO19/123907

The above method can only be used in battery packs in which an equalization circuit is implemented. Many small battery packs such as those of notebook PCs and smartphones do not have an equalization circuit implemented therein. In addition, the equalization process produces heat and energy loss in resistor discharge because it is a process to coordinate SOC between parallel cell blocks by discharging a parallel cell block having a relatively high SOC through a resistor.

### SUMMARY OF THE INVENTION

The present disclosure addresses the issue described above, and a purpose thereof is to provide a technology of easily detecting an abnormality of a battery pack in which a plurality of parallel cell blocks are connected in series.

A battery abnormality detection system according to an embodiment of the present disclosure includes: an acquisition unit that acquires voltage data for each parallel cell block of a battery pack in which a plurality of parallel cell blocks, each comprised of a plurality of cells connected in parallel, are connected in series; and an abnormality detection unit that detects, based on a voltage change in a normal parallel cell block and on a change in a voltage difference between the normal parallel cell block and a target parallel cell block, an abnormality of the target parallel cell block.

Optional combinations of the aforementioned constituting elements, and implementations of the present disclosure in the form of apparatuses, systems, methods, and programs may also be practiced as additional aspects of the present disclosure.

Embodiments will now be described, by way of example only, with reference to the accompanying drawings which are meant to be exemplary, not limiting, and wherein like elements are numbered alike in several Figures, in which:

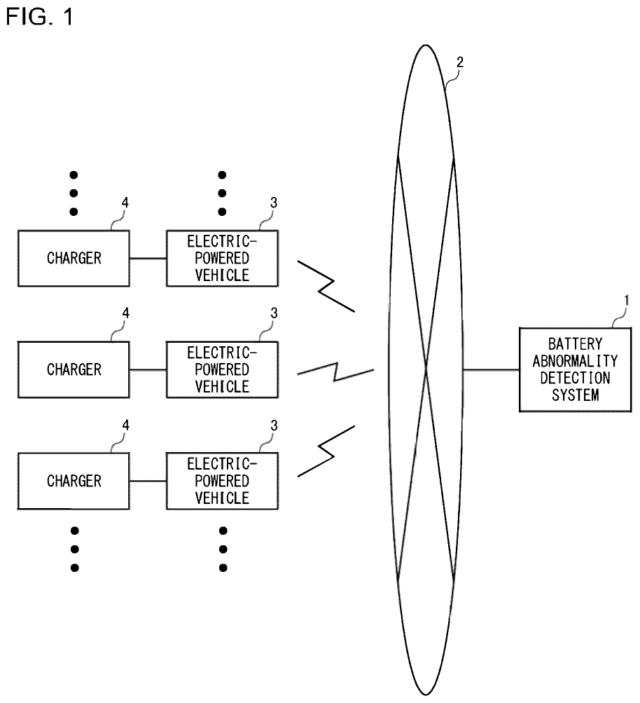

FIG. 1 is a diagram for illustrating the outline of a battery abnormality detection system according to the embodiment.

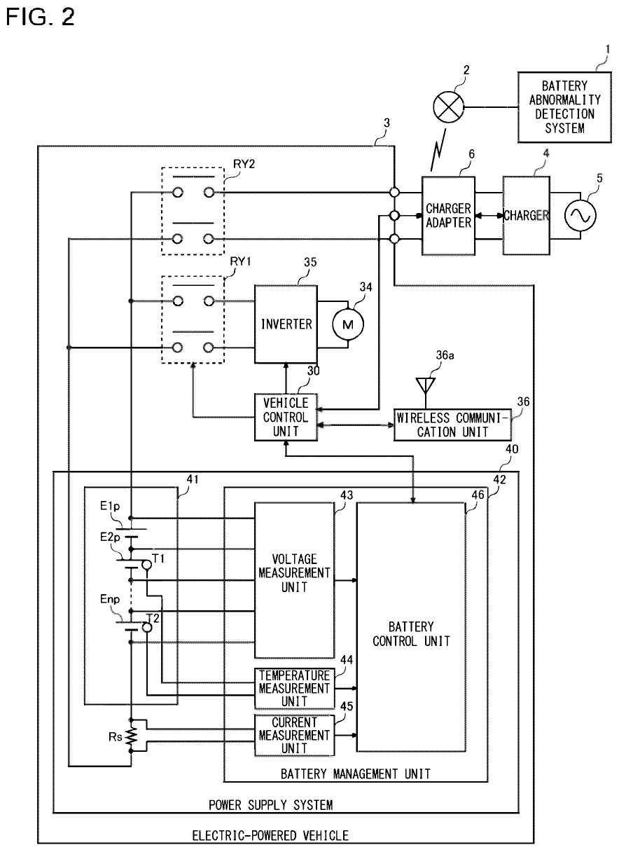

FIG. 2 is a diagram for illustrating a detailed configuration of a power supply system mounted on the electric-powered vehicle.

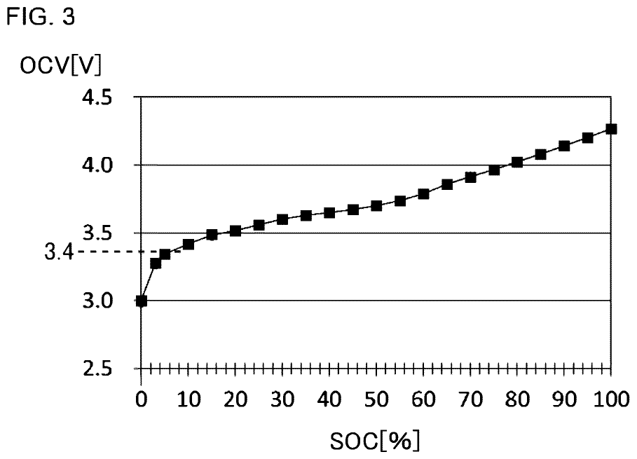

FIG. 3 is a diagram showing an example of the SOC-OCV curve.

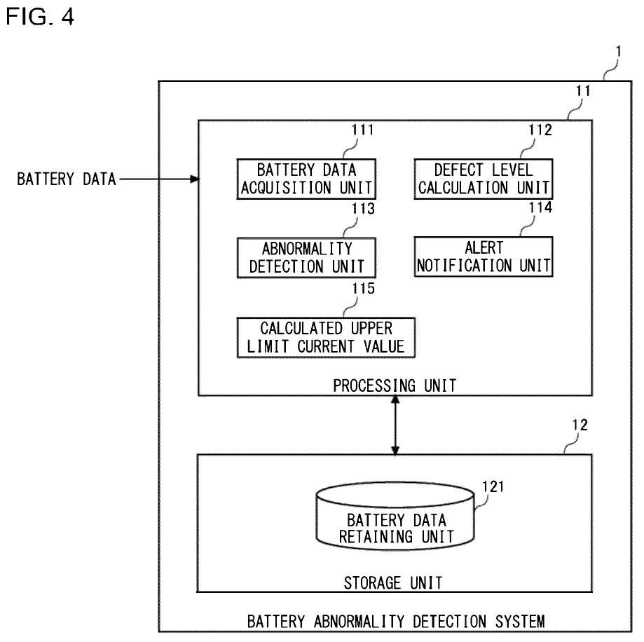

FIG. 4 is a diagram showing an exemplary configuration of the battery abnormality detection system according to the embodiment.

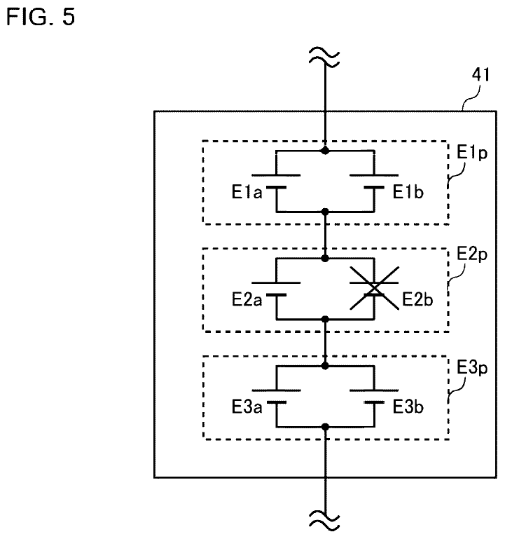

FIG. 5 is a diagram showing an example of connection of cells in the battery pack.

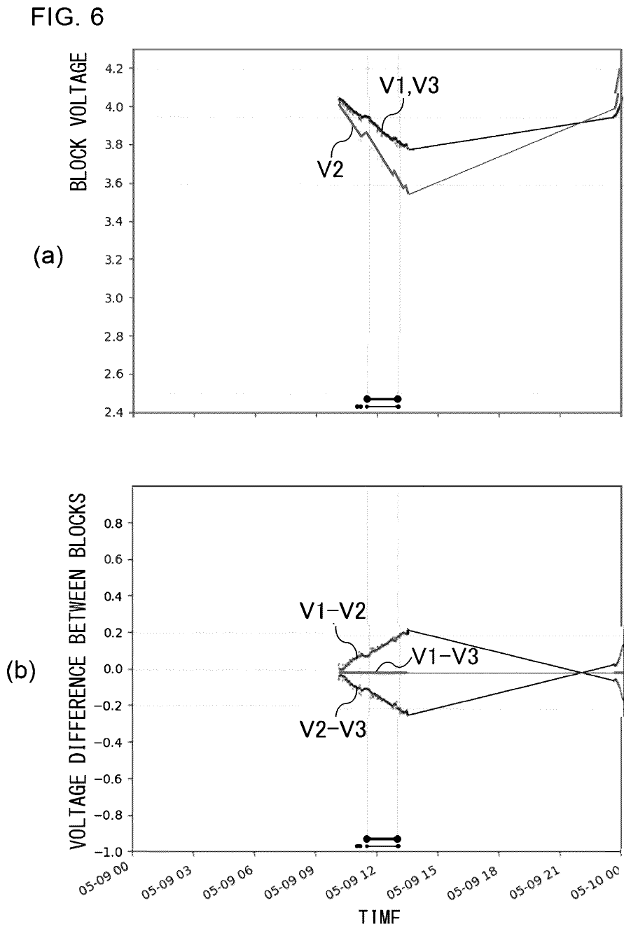

FIGS. 6A-6B show an example of voltage transition in the first to third blocks and an example of transition of voltage difference between blocks.

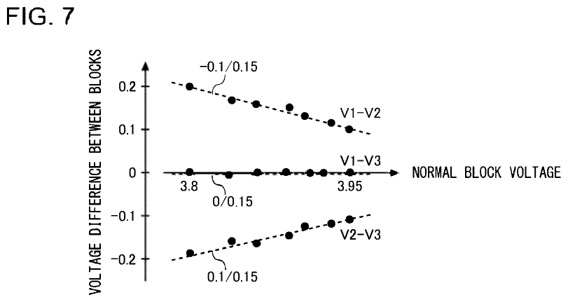

FIG. 7 is a diagram schematically showing how the voltage difference between blocks changes with respect to the voltage change in the normal block.

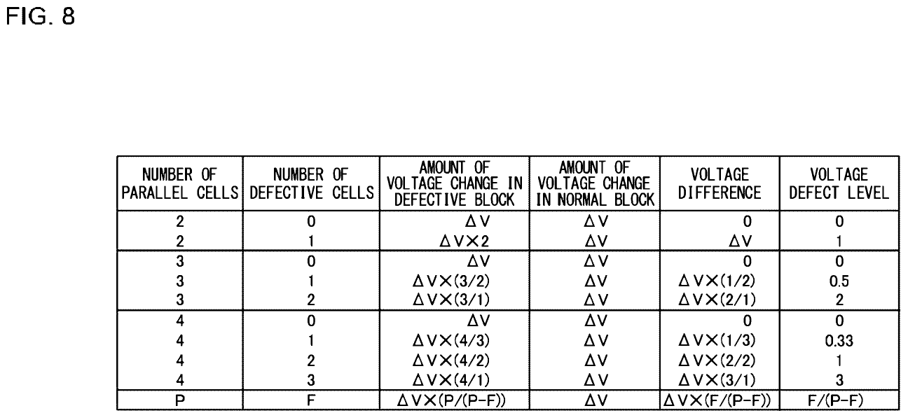

FIG. 8 is a table showing a rule to set the threshold value that should be compared with the voltage defect level.

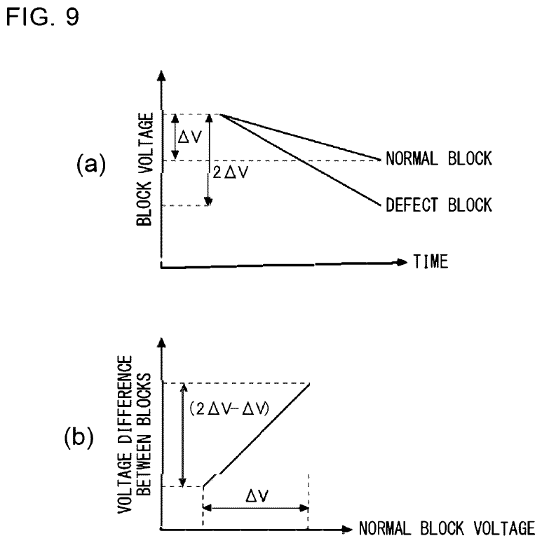

FIGS. 9A-9B are graphs showing that the voltage defect level is 1 when the number of parallel cells in the block is 2 and the number of defective cells is 1.

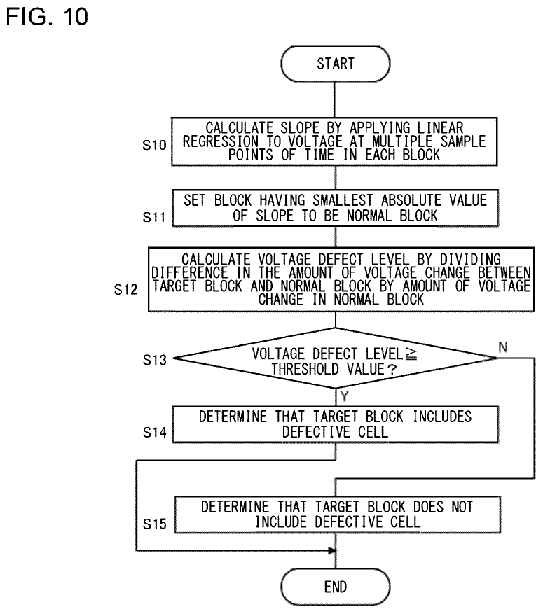

FIG. 10 is a flowchart showing the flow of a basic process for abnormality detection by the battery abnormality detection system according to the embodiment.

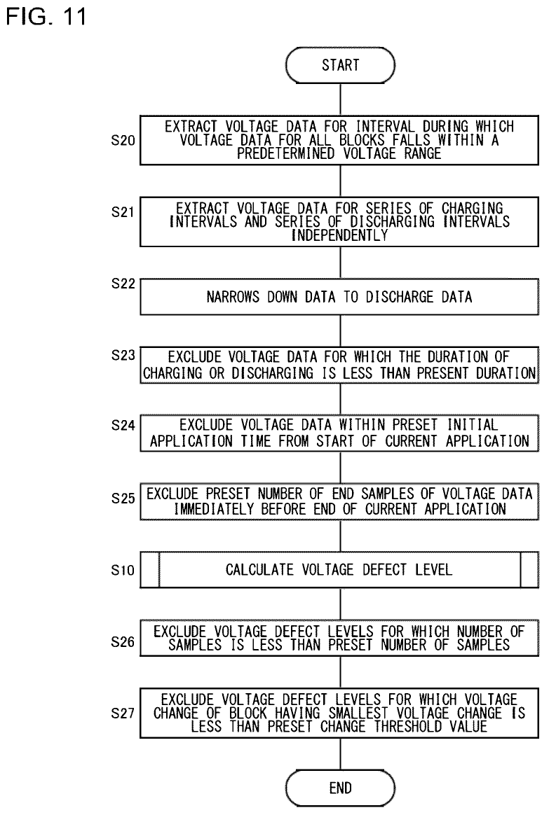

FIG. 11 is a flowchart for illustrating a specific example of a filtering process in an abnormality detection process by the battery abnormality detection system according to the embodiment.

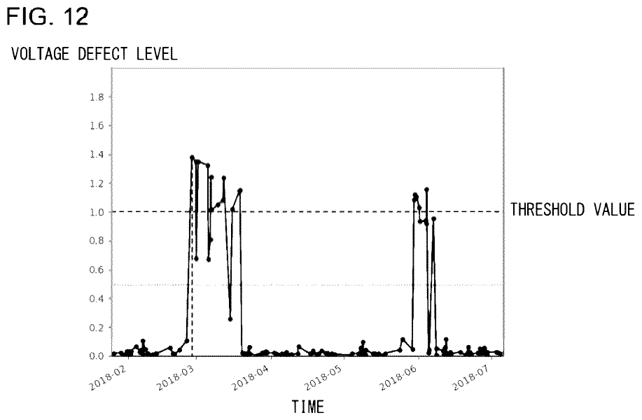

FIG. 12 is a diagram showing experimental data showing a transition of the voltage defect level of the battery pack.

### DETAILED DESCRIPTION OF THE INVENTION

The invention will now be described by reference to the preferred embodiments. This does not intend to limit the scope of the present invention, but to exemplify the invention.

FIG. 1 is a diagram for illustrating the outline of a battery abnormality detection system 1 according to the embodiment. The battery abnormality detection system 1 according to the embodiment is a system for detecting an abnormality of a parallel cell block included in a battery pack mounted on an electric-powered vehicle 3. The electric-powered vehicle 3 is inclusive of electric vehicles (EV), plug-in hybrid vehicles (PHV), hybrid vehicles (HV), but pure electric vehicles (EV) are assumed in the embodiment.

The battery abnormality detection system 1 according to the embodiment is a system used by at least one delivery company. The battery abnormality detection system 1 may, for example, be built on an in-house server provided in an in-house facility of the service provider that provides an operation management support service for the electric-powered vehicle 3 or in a data center. Alternatively, the battery abnormality detection system 1 may be built on a cloud server that is used based on a cloud service contract. Alternatively, the battery abnormality detection system 1 may be built on a plurality of servers distributed at a plurality of sites (data centers, in-house facilities). The plurality of servers may be any of a combination of a plurality of in-house servers, a combination of a plurality of cloud servers, or a combination of an in-house server and a cloud server.

The delivery company owns a plurality of electric-powered vehicles 3 and a plurality of chargers 4 and uses the plurality of electric-powered vehicles 3 for delivery business. It should be noted that the electric-powered vehicle 3 can be charged from a charger 4 other than the charger 4 provided at a delivery site.

The plurality of electric-powered vehicles 3 have a wireless communication function and can be connected to a network 2 to which the battery abnormality detection system 1 is connected. The electric-powered vehicle 3 can transmit battery data for the battery pack provided therein to the battery abnormality detection system 1 via the network 2.

The network 2 is a general term for communication channels such as the Internet, leased lines, and VPN (Virtual Private Network), and the communication medium and the protocol thereof do not matter. For example, a mobile phone network (cellular network), a wireless LAN, a wired LAN, an optical fiber network, an ADSL network, a CATV network, and the like can be used as the communication medium. For example, TCP (Transmission Control Protocol)/IP (Internet Protocol), UDP (User Datagram Protocol)/IP, Ethernet (registered trademark) and the like can be used as the communication protocol.

FIG. 2 is a diagram for illustrating a detailed configuration of a power supply system 40 mounted on the electric-powered vehicle 3. The power supply system 40 is connected to a motor 34 via a first relay RY1 and an inverter 35. The inverter 35 converts a DC power supplied from the power supply system 40 into an AC power and supplies it to the motor 34 during power running. During regeneration, the inverter 35 converts the AC power supplied from the motor 34 into a DC power and supplies it to the power supply system 40. The motor 34 is a three-phase AC motor and rotates according to the AC power supplied from the inverter 35 during power running. During regeneration, the motor 34 converts the rotational energy caused by deceleration into an AC power and supplies it to the inverter 35.

A vehicle control unit 30 is a vehicle ECU (Electronic Control Unit) that controls the entire electric-powered vehicle 3 and may be, for example, comprised of an integrated VCM (Vehicle Control Module). A wireless communication unit 36 has a modem and performs a wireless signal process for wireless connection to the network 2 via an antenna 36a. Examples of a wireless communication network to which the electric-powered vehicle 3 can be wirelessly connected include a mobile phone network (cellular network), a wireless LAN, V2I (Vehicle-to-Infrastructure), V2V (Vehicle-to-Vehicle), ETC system (Electronic Toll Collection System), and DSRC (Dedicated Short Range Communications).

The first relay RY1 is a contactor inserted between the wirings connecting the power supply system 40 and the inverter 35. The vehicle control unit 30 controls the first relay RY1 to be on (closed state) while the vehicle is running to electrically connect the power supply system 40 and the power system of the electric-powered vehicle 3. While the vehicle is not running, the vehicle control unit 30 controls the first relay RY1 to be off (open state) in principle and electrically cuts off the power supply system 40 and the power system of the electric-powered vehicle 3 from each other. Instead of a relay, a different type of switch such as a semiconductor switch may be used.

The electric-powered vehicle 3 is adapted to charge a battery pack 41 in the power supply system 40 from outside by being connected to the charger 4. In this embodiment, the electric-powered vehicle 3 is connected to the charger 4 via a charger adapter 6. The charger adapter 6 is mounted on, for example, the end of the terminal of the charger 4. When the charger adapter 6 is mounted on the charger 4, the control unit in the charger adapter 6 establishes a communication channel with the control unit in the charger 4.

The charger adapter 6 is preferably comprised of a small housing. In that case, the driver of the electric-powered vehicle 3 can easily carry the charger adapter 6 and can use the charger adapter 6 by mounting it on a charger 4 other than the charger 4 provided at the delivery base. For example, the driver can use the charger adapter 6 by mounting it on a charger 4 other than the charger 4 provided at the delivery base such as the charger 4 provided in a public facility, a commercial facility, a gas station, a car dealer, or a highway service area.

When the charger adapter 6 mounted on the charger 4 and the electric-powered vehicle 3 are connected by a charging cable, the battery pack 41 in the electric-powered vehicle 3 can be charged from the charger 4. The charger adapter 6 causes the power supplied from the charger 4 to pass through to the electric-powered vehicle 3. The charger adapter 6 has a wireless communication function and can exchange data with the battery abnormality detection system 1 via the network 2. The charger adapter 6 functions as a gateway that relays communication between the electric-powered vehicle 3 and the charger 4, between the electric-powered vehicle 3 and the battery abnormality detection system 1, and between the charger 4 and the battery abnormality detection system 1.

The charger 4 is connected to a commercial power system 5 and charges the battery pack 41 in the electric-powered vehicle 3. In the electric-powered vehicle 3, a second relay RY2 is inserted between the wirings connecting the power supply system 40 and the charger 4. Instead of a relay, a different type of switch such as a semiconductor switch may be used. A battery management unit 42 controls the second relay RY2 to be on via the vehicle control unit 30 or directly before charging is started and controls the second relay RY2 to be off after charging is completed.

In general, a battery is charged with AC in the case of normal charging and is charged with DC in the case of fast charging. In the case of charging the battery with AC (for example, single-phase 100/200 V), the AC power is converted into a DC power by an AC/DC converter (not shown) inserted between the second relay RY2 and the battery pack 41. In the case of charging the battery with DC, the charger 4 generates the DC power by rectifying the AC power supplied from the commercial power system 5 in full wave rectification and smoothing the power with a filter.

Examples of fast charging standards that can be used include CHAdeMO (registered trademark), ChaoJi, GB/T, Combo (Combined Charging System). CHAdeMO2.0 stipulates that the maximum output (specification) is 1000V×400 A=400 kW. CHAdeMO3.0 stipulates that the maximum output (specification) is 1500V×600 A=900 kW. ChaoJi stipulates that the maximum output (specification) is 1500V×600 A=900 kW. GB/T stipulates that the maximum output (specification) is 750V×250 A=185 kW. Combo stipulates that the maximum output (specification) is 900V×400 A=350 kW. CHAdeMO, ChaoJi, and GB/T use CAN (Controller Area Network) as the communication method. Combo uses PLC (Power Line Communication) as the communication method.

In addition to power lines, communication lines are also included in the charging cable in which the CAN scheme is employed. When the electric-powered vehicle 3 and the charger adapter 6 are connected by the charging cable, the vehicle control unit 30 establishes a communication channel with the control unit in the charger adapter 6. In the charging cable in which the PLC scheme is employed, a communication signal is superimposed and transmitted on the power line.

The vehicle control unit 30 establishes a communication channel with the battery management unit 42 via a vehicle-mounted network (for example, CAN or LIN (Local Interconnect Network)). When the communication standard between the vehicle control unit 30 and the control unit in the charger adapter 6 and the communication standard between the vehicle control unit 30 and the battery management unit 42 are different, the vehicle control unit 30 performs a gateway function.

The power supply system 40 mounted on the electric-powered vehicle 3 includes the battery pack 41 and the battery management unit 42. The battery pack 41 includes a plurality of parallel cell blocks E1p-Enp. A lithium ion battery cell, a nickel-metal hydride battery cell, a lead battery cell, or the like can be used as the cells included in the parallel cell blocks E1p-Enp. Hereinafter, an example of using a lithium ion battery cell (nominal voltage: 3.6-3.7 V) is assumed in this specification. The number of parallel cell blocks E1p-Enp connected in series is determined according to the drive voltage of the motor 34 (e.g., 300 V-400 V).

A shunt resistor Rs is connected in series with the plurality of parallel cell blocks E1p-Enp. The shunt resistor Rs functions as a current-sensing element. A Hall element may be used instead of the shunt resistor Rs. A plurality of temperature sensors T1, T2 for detecting the temperature of the plurality of parallel cell blocks E1p-Enp are provided in the battery pack 41. For example, a thermistor can be used as the temperature sensors T1, T2. For example, one temperature sensor may be provided for 6-8 parallel cell blocks.

The battery management unit 42 includes a voltage measurement unit 43, a temperature measurement unit 44, a current measurement unit 45, and a battery control unit 46. The nodes of the plurality of parallel cell blocks E1p-Enp connected in series and the voltage measurement unit 43 are connected by a plurality of voltage lines. The voltage measurement unit 43 measures the voltage of each parallel cell block E1p-Enp by measuring the voltage between two adjacent voltage lines respectively. The voltage measurement unit 43 transmits the voltage of each parallel cell block E1p-Enp thus measured to the battery control unit 46.

Since the voltage measurement unit 43 is at a higher voltage than the battery control unit 46, the voltage measurement unit 43 and the battery control unit 46 are connected by a communication line in an electrically insulated state. The voltage measurement unit 43 can be comprised of an ASIC (Application Specific Integrated Circuit) or a general-purpose analog front-end IC. The voltage measurement unit 43 includes a multiplexer and an A/D converter. The multiplexer successively outputs the voltage between two adjacent voltage lines to the A/D converter from top to bottom. The A/D converter converts the analog voltage input from the multiplexer into a digital value.

The temperature measurement unit 44 includes a voltage divider resistor and an A/D converter. The A/D converter converts a plurality of analog voltages divided by the plurality of temperature sensors T1, T2 and the plurality of voltage divider resistors into digital values successively and outputs them to the battery control unit 46. The battery control unit 46 measures the temperature at a plurality of observation points in the battery pack 41.

The current measurement unit 45 includes a differential amplifier and an A/D converter. The differential amplifier amplifies the voltage across the shunt resistor Rs and outputs the amplified voltage to the A/D converter. The A/D converter converts the analog voltage input from the differential amplifier into a digital value and outputs it to the battery control unit 46. The battery control unit 46 measures the current flowing through the plurality of parallel cell blocks E1p-Enp based on the digital value.

In the case an A/D converter is mounted in the battery control unit 46 and an analog input port is provided in the battery control unit 46, the temperature measurement unit 44 and the current measurement unit 45 may output an analog voltage to the battery control unit 46, and the A/D converter in the battery control unit 46 may convert the analog voltage into a digital value.

The battery control unit 46 manages the state of the plurality of parallel cell blocks E1p-Enp based on the voltage, temperature, and current of the plurality of parallel cell blocks E1p-Enp measured by the voltage measurement unit 43, the temperature measurement unit 44, and the current measurement unit 45. When an overvoltage, undervoltage, overcurrent, or temperature abnormality occurs in at least one of the plurality of parallel cell blocks E1p-Enp, the battery control unit 46 turns off the second relay RY2 or the protection relay (not shown) in the battery pack 41 to protect the parallel cell block.

The battery control unit 46 can be comprised of a microcontroller and a non-volatile memory (e.g., EEPROM (Electrically Erasable Programmable Read-Only Memory), flash memory). The battery control unit 46 estimates the SOC of each of the plurality of parallel cell blocks E1p-Enp.

The battery control unit 46 estimates SOC by combining the OCV (Open Circuit Voltage) method and the current integration method. The OCV method is a method of estimating SOC based on the OCV of each parallel cell block (≈each cell) measured by the voltage measurement unit 43 and the SOC-OCV curve of the cell. The SOC-OCV curve of the cell is created in advance based on a characteristic test by the battery manufacturer and is registered in the internal memory of the microcontroller at the time of shipment.

FIG. 3 is a diagram showing an example of the SOC-OCV curve. The shape of the SOC-OCV curve varies depending on the type of battery.

The current accumulation method is a method of estimating SOC based on the OCV at the start of charging or discharging of each parallel cell block and the integrated value of the current measured by the current measurement unit 45. In the current accumulation method, the measurement error of the current measurement unit 45 accumulates as the charging/discharging time increases. On the other hand, the OCV method is affected by the measurement error of the voltage measurement unit 43 and the error caused by the polarization voltage. It is therefore preferable to use a weighted average of the SOC estimated by the current accumulation method and the SOC estimated by the OCV method.

The battery control unit 46 periodically (for example, every 10 seconds) samples battery data including voltage, current, temperature, and SOC of each parallel cell block E1p-Enp and transmits the data to the vehicle control unit 30 via the vehicle-mounted network. The vehicle control unit 30 can transmit battery data to the battery abnormality detection system 1 in real time using the wireless communication unit 36 while the electric-powered vehicle 3 is running.

The vehicle control unit 30 may store the battery data for the electric-powered vehicle 3 in the internal memory and collectively transmit the battery data stored in the memory at a predetermined point of time. For example, the vehicle control unit 30 collectively transmits the battery data stored in the memory to a terminal apparatus at a sales office at the end of the day's business. The terminal apparatus at the sales office collectively transmits the battery data for the plurality of electric-powered vehicles 3 to the battery abnormality detection system 1 at a predetermined point of time.

Alternatively, the vehicle control unit 30 may collectively transmit the battery data stored in the memory to the charger adapter 6 or the charger 4 having a network communication function via the charging cable when the battery is charged by the charger 4. The charger adapter 6 or the charger 4 having a network communication function transmits the received battery data to the battery abnormality detection system 1. This example is effective for the electric-powered vehicle 3 that is not equipped with a wireless communication function.

FIG. 4 is a diagram showing an exemplary configuration of the battery abnormality detection system 1 according to the embodiment. The battery abnormality detection system 1 includes a processing unit 11 and a storage unit 12. The processing unit 11 includes a battery data acquisition unit 111, a defect level calculation unit 112, an abnormality detection unit 113, an alert notification unit 114, and a calculated upper limit current value 115. The function of the processing unit 11 can be realized by cooperation between hardware resources and software resources or by hardware resources alone. Hardware resources such as CPU, ROM, RAM, GPU (Graphics Processing Unit), ASIC (Application Specific Integrated Circuit), FPGA (Field Programmable Gate Array), and other LSIs can be used. Programs such as operating systems and applications can be used as software resources.

The storage unit 12 includes a battery data retaining unit 121. The storage unit 12 is inclusive of a non-volatile recording medium such as an HDD (Hard Disk Drive) and an SSD (Solid State Drive) and stores various data.

The battery data acquisition unit 111 acquires battery data from the electric-powered vehicle 3, the terminal apparatus at the sales office, or the like via the network 2. The battery data includes at least voltage data for each parallel cell blocks E1p-Enp of the battery pack 41. The battery data acquisition unit 111 stores the acquired battery data in the battery data retaining unit 121.

The abnormality detection unit 113 detects an abnormality of the target block based on a voltage change in a normal parallel cell block (hereinafter simply referred to as a normal block) and a change in voltage difference between the normal block and the target parallel cell block (hereinafter simply referred to as a target block). An abnormality of the target block is inclusive of an incidence of a defective cell in the block. A defective cell is a dysfunctional cell that occurs due to an open gas discharge valve, CID (Current Interrupt Device) activation, disconnection, poor contact, etc. An open gas discharge valve and CID activation are induced when the pressure inside the battery rises abnormally. An open gas discharge valve, CID activation, and disconnection are irreversible defects and poor contact is a reversible defect.

In this embodiment, the main object is to detect a block including a defective cell (hereinafter referred to as a defective block) non-destructively. This makes it possible to notify the user of an incidence of a cell defect, promote replacement or repair of the battery pack 41, and prevent the occurrence of an unsafe event. A specific description will be given below.

FIG. 5 is a diagram showing an example of connection of cells in the battery pack 41. Hereinafter, a specific example will be described by assuming a two (parallel)-by-three (series) battery pack 41 shown in FIG. 5. In this specific example, it is assumed that the second cell E2b of the second block E2p is a defective cell.

In this embodiment, an index called voltage defect level is used to detect a defective block. The voltage defect level is our unique index that takes advantage of the fact that, given that the same amount of current [Ah] is charged or discharged, the amount of change in OCV and SOC increases as the SOH (State Of Health) of the battery decreases. The index can be used to detect capacity abnormality of a block.

FIGS. 6A-6B show an example of voltage transition in the first to third blocks E1p-E3p and an example of transition of voltage difference between blocks. In FIGS. 6A-6B, the voltage of the first block E1p is denoted by V1, the voltage of the second block E2p is denoted by V2, and the voltage of the third block E3p is denoted by V3. The horizontal axis of FIG. 6A represents time, and the vertical axis represents each block voltage. The horizontal axis of FIG. 6B represents time, and the vertical axis represents voltage difference between respective blocks.

FIGS. 6A-6B show a state of continuous discharge for about 2 hours from around 11:30 a.m. on May 9. As shown in FIG. 6A, the voltages V1-V3 of the first to third blocks E1p-E3p decrease. The second block (defective block) E2p, which includes the defective cell, substantially behaves as a battery with a significantly reduced SOH, so that the voltage thereof drops more rapidly than the first block E1p (normal block) and the third block E3p (normal block).

FIG. 6B shows voltage differences each defined between two arbitrary blocks (a total of three combinations) of the first to third blocks E1p-E3p shown in FIG. 6A. The voltage difference between normal blocks (V1−V3) is almost zero, but the voltage difference between a normal block and a defective block (V1−V2, V2−V3) expands. The voltage defect level is an index that quantifies the speed at which the voltage difference expands.

FIG. 7 is a diagram schematically showing how the voltage difference between blocks changes with respect to the voltage change in the normal block. The block with the smallest voltage change between the start and end of a series of charging and discharging events is set to be the normal block. That is, the block with the highest SOH after a series of charging and discharging events is set to be the normal block. FIG. 7 shows the voltage change in the normal block from the start to end of the series of charging and discharging events and changes in voltage difference between blocks. The voltage of the normal block drops from 3.95 V to 3.8 V because of discharging.

In FIG. 7, the voltage difference between blocks with respect to the voltage change in the normal block is plotted, and the graph shows an approximate line derived from applying linear regression to the plots by least squares. Each approximate line will have a slope substantially proportional to the SOH difference between the blocks. The polarity of the slope changes depending on the order of subtracting the voltage between the blocks. In the example shown in FIG. 7, the normal block is the first block E1p or the third block E3p, the slope of the linear regression curve of the voltage difference (V1−V2) between the first block E1p and the second block E2p is (−0.1/0.15), the slope of the linear regression curve of the voltage difference (V1−V3) between the first block E1p and the third block E23 is (0/0.15), and the slope of the linear regression curve of the voltage difference (V2−V3) between the second block E2p and the third block E3p is (0.1/0.15).

In this embodiment, the value derived from normalizing the speed of expansion of the voltage difference between the blocks according to the voltage change in the normal block is defined as the voltage defect level of each target block. The larger the value of voltage defect level, the smaller the amount of charge or discharge required to produce a great voltage difference between the blocks. Of the voltage defect levels of the respective target blocks, the one with the largest absolute value is defined as the voltage defect level of the battery pack 41. That is, the voltage defect level of the battery pack 41 is defined as the voltage defect level of the block having the SOH deviates most from the normal block. In the example shown in FIG. 7, the voltage defect level of the battery pack 41 is 0.67 (=0.1/0.15).

The threshold value that should be compared with the voltage defect level will now be described. It is desirable to determine an abnormality when a predetermined number or more of the parallel cells included in the block is defective (completely malfunctioning). However, the voltage defect level described above is an index that represents the SOH deviation between blocks, and so some numerical value will be derived equally when a SOH variance occurs. It is therefore necessary to set an appropriate threshold for the voltage defect level to distinguish between a defect and a tolerable SOH variance.

FIG. 8 is a table that summarizes a rule to set the threshold value that should be compared with the voltage defect level. In this example, the threshold value is set by assuming that the SOC-OCV curve has a proportional relationship. In other words, it is assumed that when the amount of change in SOC is doubled, the amount of change in OCV will also be doubled. In this embodiment, the voltage defect level is defined as (the amount of voltage change in the defective block−the amount of voltage change in the normal block)/the amount of voltage change in the normal block.

Hereinafter, the number of parallel cells in the block is denoted by P, and the number of defective cells in the block is denoted by F. When F cells of the P parallel cells becomes defective, the remaining normal (P−F) cells undergo the current load on the P cells. Denoting the amount of voltage change that occurs when the normal block is charged or discharged by ΔV, the amount of voltage change in the defective block is given by ΔV×(P/(P−F)). In this case, the voltage difference between the normal block and the defective block is given by ΔV−(ΔV×(P/(P−F))=ΔV×(F/(P−F)). The voltage defect level is given by ΔV×(F/(P−F))/ΔV=F/(P−F).

Given that, for example, the number of parallel cells in the block is 4 (P=4) and one of the cells becomes defective (F=1), the voltage defect level is 1/(4−1)=0333. When one cell becomes defective (F=2), the voltage defect level will be 2/(4−2)=1. The voltage defect level is a numerical value solely determined by the ratio between the number of parallel cells in the block and the number of defective cells. The voltage defect level will be 0.333 either in the case 1 out of 4 parallel cells becomes defective or in the case 10 out of 40 parallel cells become defective.

The voltage defect level is an index indicating an increase in the current load applied to each remaining normal cell in the presence of a defective cell when the current load applied to each cell in the absence of a cell defect in the block is defined as 1. For example, the voltage defect level=0.333 indicates that the current load on each remaining normal cell increases by 1.333 (1+0.333) times due to the occurrence of a cell defect in the block.

The designer may set the threshold value to 0.333 in the case an abnormality is detected when a defect occurs in ¼ or more of the parallel cells in the block, set the threshold value to 0.5 in the case an abnormality is detected when a defect occurs in ⅓ or more of the cells, or set the threshold value to 1 in the case an abnormality is detected when a defect occurs in ½ or more of the cells. In this way, the designer can adjust the sensitivity of defect detection as desired.

FIGS. 9A-9B are graphs showing that the voltage defect level is 1 when the number of parallel cells P in the block is 2 and the number of defective cells F is 1. FIG. 9A shows voltage transitions in the defective block and in the normal block. FIG. 9B shows a relationship between the voltage difference between the defective block and the normal block and the voltage of the normal block.

In the case the number of parallel cells P is 2 and the number of defective cells F is 1, the SOH of the defective block can be regarded as ½ the SOH of the normal block so that the amount of voltage change in the defective block is twice (2ΔV) the amount of voltage change ΔV in the normal block. Therefore, the voltage defect level is (2ΔV−ΔV)/ΔV=1.

FIG. 10 is a flowchart showing the flow of a basic process for abnormality detection by the battery abnormality detection system 1 according to the embodiment. The defect level calculation unit 112 calculates the slope of voltage change in each block by applying linear regression to voltage data for each block at a plurality of sample points of time (S10). The defect level calculation unit 112 refers to the slope of voltage change calculated for the respective blocks and sets the block having the smallest absolute value to be the normal block (S11). The defect level calculation unit 112 calculates the voltage defect level of the target block by dividing (normalizing) the difference in the amount of voltage change between the target block and the normal block by the amount of voltage change in the normal block (S12).

That is, denoting the amount of voltage change in the normal block by ΔV and the amount of voltage change in the target block by ΔVn, the defect level calculation unit 112 calculates |(ΔVn−ΔV)|/ΔV to calculate the voltage defect level of the target block.

The abnormality detection unit 113 determines that the target block contains a defective cell (S14) when the voltage defect level is equal to or greater than the threshold value (Y in S13) and determines that the target block does not contain a defective cell (S15) when the voltage defect level is less than the threshold value (N of S13).

A description will now be given of a method for improving the accuracy of calculation of the voltage defect level by filtering the voltage data used. The voltage data retained in the battery data retaining unit 121 and analyzed for cell defect covers a period from a point of time a predetermined number of days (e.g., three days) into the past from a period targeted for analysis to the present point of time. This is to ensure that the charging and discharging operation spanned across days can be handled as a series of data. In this embodiment, the voltage data for each block during a charging/discharging interval is extracted from the voltage data subject to analysis based on a predetermined filtering condition, and the voltage defect level is calculated based on the voltage data during each charging/discharging interval. The algorithm for detecting a cell defect described above is based on the speed at which the voltage difference between blocks expands during charging and discharging. A description will now be given of a specific example of a filtering process for effectively suppressing the noise component contained in the voltage data during charging/discharging.

FIG. 11 is a flowchart for illustrating a specific example of a filtering process in an abnormality detection process by the battery abnormality detection system 1 according to the embodiment. The defect level calculation unit 112 extracts voltage data for an interval during which the voltage data for all blocks included in the battery pack 41 falls within a predetermined voltage range (for example, 3.4-4.2 V) (S20). This filtering condition is a condition for excluding a low SOC zone (see FIG. 3 above) where the voltage change during charging and discharging is large and a SOC zone during CV (constant voltage) charging during which the current changes significantly. In normal CCCV charging, CC charging is switched to CV charging in a high SOC zone near the target SOC.

The defect level calculation unit 112 extracts voltage data for a series of charging intervals and a series of discharging intervals independently (S21). When a time jump of a preset period of time (for example, 30 minutes) or longer occurs while a current is applied, the charging or discharging event is temporarily terminated. Further, an interval containing voltage data outside the predetermined voltage range is defined as an interval during which the battery is not charged or discharged. This filtering condition is a condition for stabilizing the voltage behavior of each block by not mixing charging and discharging.

The defect level calculation unit 112 narrows down the voltage data to discharge data (S22). This filtering condition is a condition for excluding voltage data during CV charging. It should be noted that the data may be narrowed down to charge data, or both data may be used.

The defect level calculation unit 112 excludes voltage data for which the duration of charging or discharging is less than a preset duration (e.g., 10 minutes) (S23). This filtering condition is a condition for excluding short-term charge/discharge data for which it is difficult to grasp the behavior of the expanding voltage difference between blocks.

The defect level calculation unit 112 excludes voltage data within a preset initial application time (for example, 5 minutes) from the start of current application (S24). This filtering condition is a condition for excluding voltage data in a transient response zone where fluctuations in voltage difference between blocks are unstable.

The defect level calculation unit 112 excludes a preset number of end samples of (e.g., three) voltage data immediately before the end of current application (S25). This filtering condition is a condition for preventing mixing of a transient response of a rest and relaxation voltage at the end of current application caused by time misalignment of voltage and current samples of some analysis data.

The defect level calculation unit 112 calculates the voltage defect level according to the flowchart shown in FIG. 10 (S10). The defect level calculation unit 112 excludes voltage defect levels for which the number of samples relied upon for voltage defect level calculation is less than a preset number of samples (for example, 10) (S26). This filtering condition is a condition for retaining only data having a high accuracy of linear regression performed when the voltage defect level is calculated.

The defect level calculation unit 112 excludes voltage defect levels for which the voltage change of the block having the smallest voltage change is less than a preset change threshold value (for example, 0.1 V) (S27). This filtering condition is a condition for retaining only data having a high accuracy of linear regression performed when the voltage defect level is calculated.

The sequence of the filtering process shown in FIG. 11 is an example, and the process may be performed in a different sequence. Further, it is not necessary to execute all filtering steps shown in FIG. 11, and only some of them may be executed.

So far, we have described a process in which the abnormality detection unit 113 detects presence or absence of a defective block that includes a defective cell, based on the voltage defect level. The abnormality detection unit 113 can perform an abnormality detection in the battery pack 41 other than detection of a defective block. The abnormality detection unit 113 determines that the cells in the target block include a cell in which the SOH degradation is accelerating with respect to the other cells, when the voltage defect level of the target block is less than the threshold value and is gradually increasing. For example, the voltage defect level increases in a block that includes a cell that is rapidly degrading.

The abnormality detection unit 113 determines that the SOC of the target block is deviant when the voltage defect level of the target block is less than the threshold value and when, in that state, the voltage difference between the target block and the normal block is equal to or more than a predetermined value continuously for a predetermined period of time or longer. The predetermined value and the predetermined period of time are set based on a condition whereby the designer determines SOC variance. When there is a voltage difference between blocks and the voltage difference does not expand, it can be considered that the SOH is substantially the same among the blocks and the SOC differs between the blocks.

When an abnormality occurs in the target block, the alert notification unit 114 alerts the source of transmission of the battery data (for example, the electric-powered vehicle 3 or the terminal apparatus at the sales office) via the network 2. For example, the alert notification unit 114 issues an alert that includes at least one of a message prompting battery replacement or repair, an instruction for immediate stop or stop after a certain period of time, and an instruction for limiting the current to an upper limit current.

In the case an instruction for limiting the current to the upper limit current is given, the calculated upper limit current value 115 calculates the upper limit current value allowed to flow in the battery pack 41 based on the voltage defect level of the battery pack 41. As described above, the voltage defect level is an index indicating an increase in the current load applied to each remaining cell when a defective cell occurs. The calculated upper limit current value 115 calculates the upper limit current value to cancel out the increase in the current load applied to each remaining cell in the defective block. When the voltage defect level is 0.333, for example, the upper limit current value is limited to 0.667 times the rated current value. This suppresses the occurrence of an unsafe event such as lithium precipitation due to the application of an overcurrent to the remaining cell in the defective block.

When the electric-powered vehicle 3 or the terminal apparatus at the sales office receives the above alert from the battery abnormality detection system 1, the electric-powered vehicle 3 or the terminal apparatus performs at least one of the actions including: displaying an alert message on a display unit (not shown); causing the vehicle control unit 30 of the electric-powered vehicle 3 to stop the electric-powered vehicle 3; and causing the battery management unit 42 to limit an upper limit value of the current flowing in the battery pack 41 to the received upper limit current value.

Further, when the voltage defect level of the target block is less than the threshold value and is gradually increasing, expansion of SOH variance is predicted. The abnormality detection unit 113 estimates a period of time until the SOH variance reaches a predetermined value. The predetermined value is set to be the value of SOH variance that is defined as a value at the end of use in each application of the battery pack 41. The alert notification unit 114 issues an alert including a period of time until the end of use of the battery pack 41 and a message prompting prior battery replacement or repair.

FIG. 12 is a diagram showing experimental data showing a transition of the voltage defect level of the battery pack 41. In this example, the transition of the voltage defect level of the two (parallel)-by-three (series) battery pack 41 mounted on a notebook PC is shown. The threshold value for detecting the presence or absence of a defective block is set to 1. In this example, the value of the voltage defect level exceeds 1 and then falls below 1 and, again, exceeds 1 and then falls below 1. It can be presumed that this behavior is not due to an irreversible defect such as CID activation but due to a defect caused by poor terminal connection.

To suppress false detection due to noise included in voltage data, the abnormality detection unit 113 may determine that a defective block has occurred when a data segment subject to analysis in which the value of the voltage defect level is 1 or more is detected a plurality of times (for example, 3 times) continuously. Similarly, the abnormality detection unit 113 may determine that the defective block has disappeared (energization of the defective cell is resumed) when the value of the voltage defect level becomes 1 or more and then a data segment subject to analysis in which the value of the voltage defect level is less than 1 is detected a plurality of times (for example, 3 times) continuously.

Alternatively, the abnormality detection unit 113 may compare a value derived from subjecting the value of voltage defect level in the data segment subject to analysis to moving averaging with a threshold value. In this case, too, false detection due to noise can be suppressed.

As described above, according to this embodiment, an abnormality of the battery pack 41 in which a plurality of blocks are connected in series can be easily detected without destructing the battery pack 41 by referring to the behavior of voltage data for the plurality of blocks. In this embodiment, it is easy to distinguish between an SOH degradation and a defect by calculating, based on the voltage data for each block, the voltage defect level that quantifies the amount of variance in SOH degradation between blocks, and by comparing the voltage defect level with the threshold value.

Since the voltage defect level is an index that quantifies the abnormality of the target block, it is possible to predict a period of time until an intolerable abnormality occurs based on the voltage defect level. It is also possible to determine whether the operation should be stopped immediately. In addition, an increase in the current load in the defective block can be quantified by the voltage defect level so that it is also possible to control the current to offset the increase in the current load. In that case, it is possible to suppress the flow of overcurrent in the remaining cell in the defective block without stopping the current. It is also possible to detect SOC deviance between blocks.

Further, since it is not necessary to implement an equalization circuit, the disclosure can also be used in the battery pack 41 that does not have an equalization circuit implemented therein. In addition, since the voltage data during charging and discharging is used, the opportunity for abnormality detection can be increased as compared with the method of detecting an abnormality during the equalization process. The equalization process is basically performed in a time zone other than during actual use. The equalization process is not performed frequently because it is not basically performed unless the SOC variance becomes large. It is further possible, according to the disclosure, to detect an abnormality of the battery pack 41 without generating heat or energy loss such as in the case of equalized discharge.

Further, by determining the voltage defect level by normalization according to the amount of voltage change in the normal block, the influence of environmental factors (such as temperature factor) can be offset between blocks, and the speed of expansion of voltage difference between blocks can be estimated with high accuracy.

Given above is a description of the present disclosure based on the embodiment. The embodiment is intended to be illustrative only and it will be understood by those skilled in the art that various modifications to combinations of constituting elements and processes are possible and that such modifications are also within the scope of the present disclosure.

In the above-described embodiment, the voltage defect level (=(the amount of voltage change in the defective block−the amount of voltage change in the normal block)/the amount of voltage change in the normal block) was used. Instead of the voltage defect level, however, the SOC defect level (=(the amount of SOC change in the defective block−the amount of SOC change in the normal block)/the amount of SOC change in the normal block) may be used. When SOC data is included in the battery data for each block acquired from the electric-powered vehicle 3 or the terminal apparatus at the sales office, the defect level calculation unit 112 can calculate the SOC defect level using the SOC data.

Further, when the battery data for each block acquired from the electric-powered vehicle 3 or the terminal apparatus at the sales office does not include SOC data but includes current data and when the internal resistance and the SOC-OCV curve of the cell included in each block are known, the defect level calculation unit 112 can estimate the SOC of each block at each sample point of time as described below. That is, the defect level calculation unit 112 calculates the OCV from the voltage data (CCV) at each sample point of time during charging or discharging, taking into account the voltage fluctuation based on the current data and the internal resistance at each sample point of time. The defect level calculation unit 112 estimates the SOC by applying the OCV thus calculated to the SOC-OCV curve.

Our experiment shows that there is substantially no difference in accuracy between using the voltage defect level and using the SOC defect level, and either may be used. The voltage defect level does not require data other than voltage data and so can be said to be a simple detection method. Given that the parameters can be obtained ideally (in practice, the attempt is affected by, for example, changes in the shape of the SOC-OCV curve due to degradation), the SOH variance between blocks can be estimated more precisely by using the SOC defect level.

In the above-described embodiment, the voltage defect level is defined as (the amount of voltage change in the defective block−the amount of voltage change in the normal block)/the amount of voltage change in the normal block. Alternatively, the voltage defect level may be defined as the amount of voltage change in the normal block/(the amount of voltage change in the defective block−the amount of voltage change in the normal block). Still alternatively, the SOC defect level may be defined as the amount of SOC change in the normal block/(the amount of SOC change in the defective block−the amount of SOC change in the normal block).

In the above-described embodiment, an example of detecting an abnormality of the battery pack 41 mounted on the electric-powered vehicle 3 using the battery abnormality detection system 1 connected to the network 2 has been described. The battery abnormality detection system 1 may be incorporated in the battery control unit 46. Alternatively, the battery abnormality detection system 1 may be incorporated in the charger 4 or the charger adapter 6.

Further, the battery abnormality detection system 1 according to the present disclosure is not limited to abnormality detection in the battery pack 41 mounted on the electric-powered vehicle 3. For example, the system can also be applied to abnormality detection in battery packs 41 mounted on electric ships, multicopters (drones), electric motorcycles, electric bicycles, stationary electricity storage systems, smartphones, tablets, notebook PCs, and the like. In particular, the system is useful to detect an abnormality of the battery pack 41 mounted on smartphones, tablets, notebook PCs, or the like, which often does not have an equalization circuit implement therein.

The embodiment may be defined by the following items.

### [Item 1]

A battery abnormality detection system (1) including:
an acquisition unit (111) that acquires voltage data for each parallel cell block (E1p-Enp) of a battery pack (41) in which a plurality of parallel cell blocks (E1p-Enp), each comprised of a plurality of cells connected in parallel, are connected in series; and
an abnormality detection unit (113) that detects, based on a voltage change in a normal parallel cell block (E1p) and on a change in a voltage difference between the normal parallel cell block (E1p) and a target parallel cell block (E2p), an abnormality of the target parallel cell block (E2p).

Accordingly, it is possible to detect an abnormality of the battery pack (41) in which a plurality of parallel cell blocks (E1p-Enp) are connected in series easily.

### [Item 2]

The battery abnormality detection system (1) according to Item 1, further comprising:
denoting the voltage change in the normal parallel cell block (E1p) by ΔV and a voltage change in the target parallel cell block (E2p) by ΔVn,
a defect level calculation unit (112) that calculates |(ΔVn−ΔV)|/ΔV to calculate a voltage defect level,
wherein the abnormality detection unit (113) determines that a cell defect occurs in the target parallel cell block (E2p) when the voltage defect level is equal to or greater than a threshold value.

Accordingly, it is possible to determine the presence or absence of a defective cell based on an index that quantifies an abnormality of each parallel cell block (E1p-Enp).

### [Item 3]

The battery abnormality detection system (1) according to Item 2,
wherein, denoting the number of cells included in a parallel cell block (E1p-Enp) by P and the number of cell defects included in a parallel cell block (E2p) that should be detected as an incidence of a defect by F, the threshold value is set to F/(P−F).

Accordingly, it is possible to set a threshold value suited to the designer's intent.

### [Item 4]

The battery abnormality detection system (1) according to Item 2 or 3,
wherein the defect level calculation unit (112) calculates a voltage change in each parallel cell block (E1p-Enp) by applying linear regression to a preset number or more of samples of voltage data.

Accordingly, it is possible to suppress the noise component contained in the voltage data effectively.

### [Item 5]

The battery abnormality detection system (1) according to any one of Items 2 through 4,
wherein the defect level calculation unit (112) calculates the voltage defect level by using voltage data for an interval during which the voltage data for all parallel cell blocks (E1p-Enp) falls within a predetermined voltage range.

Accordingly, it is possible to suppress the noise component contained in the voltage data effectively.

### [Item 6]

The battery abnormality detection system (1) according to any one of Items 2 through 5,
wherein the abnormality detection unit (113) determines that the cells in the target parallel cell block (E2p) include a cell in which SOH (State Of Health) degradation is accelerating, when the voltage defect level of the target parallel cell block (E2p) is less than the threshold value and is gradually increasing.

Accordingly, it is possible to detect a variance in SOH degradation between cells that does not lead to a defect.

### [Item 7]

The battery abnormality detection system (1) according to any one of Items 2 through 6,
the abnormality detection unit (113) determines that SOC (State Of Charge) of the target parallel cell block (E2p) is deviant when the voltage defect level of the target parallel cell block (E2p) is less than the threshold value and when, in that state, the voltage difference from the normal parallel cell block (E1p) is equal to or more than a predetermined value continuously for a predetermined period of time or longer.

Accordingly, it is possible to detect an SOC variance between the parallel cell blocks (E1p-Enp).

### [Item 8]

The battery abnormality detection system (1) according to any one of Items 2 through 6, further including:
an alert notification unit (114) that issues an alert when an abnormality occurs in the target parallel cell block (E2p).

Accordingly, it is possible to prompt a user for battery replacement, etc.

### [Item 9]

The battery abnormality detection system (1) according to Item 8, further including:
an upper limit current value calculation unit (115) that calculates an upper limit current value allowed to flow in the battery pack (41), based on the voltage defect level,
wherein the alert notification unit (114) issues an alert that includes an instruction for limiting a current to the upper limit current value.

Accordingly, it is possible to suppress the flow of overcurrent in the remaining cell in the parallel cell block that includes the defective cell.

### [Item 10]

A battery abnormality detection method including:
acquiring voltage data for each parallel cell block (E1p-Enp) of a battery pack (41) in which a plurality of parallel cell blocks (E1p-Enp), each comprised of a plurality of cells connected in parallel, are connected in series; and
detecting, based on a voltage change in a normal parallel cell block (E1p) and on a change in a voltage difference between the normal parallel cell block (E1p) and a target parallel cell block (E2p), an abnormality of the target parallel cell block (E2p).

Accordingly, it is possible to detect an abnormality of the battery pack (41) in which a plurality of parallel cell blocks (E1p-Enp) are connected in series easily.

### [Item 11]

A battery abnormality detection program comprising computer-implemented modules including:
a module that acquires voltage data for each parallel cell block (E1p-Enp) of a battery pack (41) in which a plurality of parallel cell blocks (E1p-Enp), each comprised of a plurality of cells connected in parallel, are connected in series; and
a module that detects, based on a voltage change in a normal parallel cell block (E1p) and on a change in a voltage difference between the normal parallel cell block (E1p) and a target parallel cell block (E2p), an abnormality of the target parallel cell block (E2p).

Accordingly, it is possible to detect an abnormality of the battery pack (41) in which a plurality of parallel cell blocks (E1p-Enp) are connected in series easily.

### [Item 12]

A battery abnormality detection system (1) including:
an acquisition unit (111) that acquires SOC data for each parallel cell block (E1p-Enp) of a battery pack (41) in which a plurality of parallel cell blocks (E1p-Enp), each comprised of a plurality of cells connected in parallel, are connected in series; and
an abnormality detection unit (113) that detects, based on an SOC change in a normal parallel cell block (E1p) and on a change in an SOC difference between the normal parallel cell block (E1p) and a target parallel cell block (E2p), an abnormality of the target parallel cell block (E2p).

Accordingly, it is possible to detect an abnormality of the battery pack (41) in which a plurality of parallel cell blocks (E1p-Enp) are connected in series easily.

### [Item 13]

The battery abnormality detection system (1) according to Item 12, further including:
denoting the SOC change in the normal parallel cell block (E1p) by Δsoc and an SOC change in the target parallel cell block (E2p) by Δsocn,
a defect level calculation unit (112) that calculates |(Δsocn−Δsoc)|/ΔV to calculate an SOC defect level,
wherein the abnormality detection unit (113) determines that a cell defect occurs in the target parallel cell block (E2p) when the SOC defect level is equal to or greater than a threshold value.

Accordingly, it is possible to detect an abnormality of the battery pack (41) in which a plurality of parallel cell blocks (E1p-Enp) are connected in series easily.

### [Item 14]

A battery abnormality detection method including:
acquiring SOC data for each parallel cell block (E1p-Enp) of a battery pack (41) in which a plurality of parallel cell blocks (E1p-Enp), each comprised of a plurality of cells connected in parallel, are connected in series; and
detecting, based on an SOC change in a normal parallel cell block (E1p) and on a change in an SOC difference between the normal parallel cell block (E1p) and a target parallel cell block (E2p), an abnormality of the target parallel cell block (E2p).

Accordingly, it is possible to detect an abnormality of the battery pack (41) in which a plurality of parallel cell blocks (E1p-Enp) are connected in series easily.

### [Item 15]

A battery abnormality detection program comprising computer-implemented modules including:
a module that acquires SOC data for each parallel cell block (E1p-Enp) of a battery pack (41) in which a plurality of parallel cell blocks (E1p-Enp), each comprised of a plurality of cells connected in parallel, are connected in series; and
a module that detects, based on an SOC change in a normal parallel cell block (E1p) and on a change in an SOC difference between the normal parallel cell block (E1p) and a target parallel cell block (E2p), an abnormality of the target parallel cell block (E2p).

Accordingly, it is possible to detect an abnormality of the battery pack (41) in which a plurality of parallel cell blocks (E1p-Enp) are connected in series easily.

1. A battery abnormality detection system comprising:
an acquisition unit that acquires voltage data for each parallel cell block of a battery pack in which a plurality of parallel cell blocks, each comprised of a plurality of cells connected in parallel, are connected in series; and
an abnormality detection unit that detects, based on a voltage change in a normal parallel cell block and on a change in a voltage difference between the normal parallel cell block and a target parallel cell block, an abnormality of the target parallel cell block.

2. The battery abnormality detection system according to claim 1, further comprising:
denoting the voltage change in the normal parallel cell block by ΔV and a voltage change in the target parallel cell block by ΔVn,
a defect level calculation unit that calculates |(ΔVn−ΔV)|/ΔV to calculate a voltage defect level,
wherein the abnormality detection unit determines that a cell defect occurs in the target parallel cell block when the voltage defect level is equal to or greater than a threshold value.

3. The battery abnormality detection system according to claim 2,
wherein, denoting the number of cells included in a parallel cell block by P and the number of cell defects included in a parallel cell block that should be detected as an incidence of a defect by F, the threshold value is set to F/(P−F).

4. The battery abnormality detection system according to claim 2,
wherein the defect level calculation unit calculates a voltage change in each parallel cell block by applying linear regression to a preset number or more of samples of voltage data.

5. The battery abnormality detection system according to claim 2,
wherein the defect level calculation unit calculates the voltage defect level by using voltage data for an interval during which the voltage data for all parallel cell blocks falls within a predetermined voltage range.

6. The battery abnormality detection system according to claim 2,
wherein the abnormality detection unit determines that the cells in the target parallel cell block include a cell in which SOH (State Of Health) degradation is accelerating, when the voltage defect level of the target parallel cell block is less than the threshold value and is gradually increasing.

7. The battery abnormality detection system according to claim 2,
the abnormality detection unit determines that SOC (State Of Charge) of the target parallel cell block is deviant when the voltage defect level of the target parallel cell block is less than the threshold value and when, in that state, the voltage difference from the normal parallel cell block is equal to or more than a predetermined value continuously for a predetermined period of time or longer.

8. The battery abnormality detection system according to claim 2, further comprising:
an alert notification unit that issues an alert when an abnormality occurs in the target parallel cell block.

9. The battery abnormality detection system according to claim 8, further comprising:
an upper limit current value calculation unit that calculates an upper limit current value allowed to flow in the battery pack, based on the voltage defect level,
wherein the alert notification unit issues an alert that includes an instruction for limiting a current to the upper limit current value.

10. A battery abnormality detection method comprising:
acquiring voltage data for each parallel cell block of a battery pack in which a plurality of parallel cell blocks, each comprised of a plurality of cells connected in parallel, are connected in series; and
detecting, based on a voltage change in a normal parallel cell block and on a change in a voltage difference between the normal parallel cell block and a target parallel cell block, an abnormality of the target parallel cell block.

11. A non-transitory computer-readable recording medium having embodied thereon a battery abnormality detection program comprising computer-implemented modules including:
a module that acquires voltage data for each parallel cell block of a battery pack in which a plurality of parallel cell blocks, each comprised of a plurality of cells connected in parallel, are connected in series; and
a module that detects, based on a voltage change in a normal parallel cell block and on a change in a voltage difference between the normal parallel cell block and a target parallel cell block, an abnormality of the target parallel cell block.
